(19) United States
(12) Patent Application Publication
(10) Pub. No.: US 2023/0307314 A1
(43) Pub. Date: Sep. 28, 2023

(54) DIRECT BOND COPPER SUBSTRATE WITH METAL FILLED CERAMIC SUBSTRATE INDENTATIONS

(71) Applicant: Texas Instruments Incorporated, Dallas, TX (US)

(72) Inventors: Kwnag-Soo Kim, Sunnyvale, CA (US); Makoto Shibuya, Beppu City (JP); Vivek Kishorechand Arora, San Jose, CA (US)

(21) Appl. No.: 17/703,787

(22) Filed: Mar. 24, 2022

(51) Int. Cl. H01L 23/373; H01L 25/16; H01L 21/48

(52) U.S. Cl. CPC H01L 23/3735; H01L 25/16; H01L 21/4857; H01L 24/32

(57) ABSTRACT

A semiconductor device includes a direct bonded copper (DBC) substrate including a plurality of indentations in at least a top side of a ceramic substrate. The plurality of indentations are filled with a metal filler to provide metal filled dimples. A top copper layer is a patterned layer that is on the top side and provides leads, and there is at least one semiconductor die having bond pads electrically connected to the leads.

### FIELD

This Disclosure relates to direct bonded copper (DBC) substrates and semiconductor devices including at least one semiconductor die mounted on a DBC substrate.

### BACKGROUND

DBC substrates are commonly used in power modules, because of their high relative thermal conductivity as compared to other types of package substrates. A DBC substrate comprises a ceramic substrate that comprises a material comprising an oxide or nitride dielectric (typically alumina) with a sheet of copper bonded to one or both sides of the ceramic substrate generally implemented by a high-temperature oxidation or nitridation Bonding process can comprise heating the copper sheets and ceramic substrate to a carefully controlled temperature in an atmosphere of nitrogen for ceramic oxide materials containing about 20 to 40 parts per million (ppm) of oxygen. Under these conditions, a copper-oxygen eutectic forms at the copper to a ceramic interface which bonds both to the copper of the copper sheets and the oxide of the ceramic substrates. The top copper layer can be patterned prior to bonding or chemically etched after bonding using printed circuit board (PCB) technology to form a pattern including die pads for wirebond packages, leads, and traces for an electrical circuit, while the bottom copper layer usually remains un-patterned.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed aspects recognize conventional DBC substrates can be prone to delamination due to a significant coefficient of thermal expansion (CTE) mismatch between the copper layer(s) and the ceramic substrate. Although the copper layers can include dimples (full or half thickness dimples) to try to reduce this delamination risk, the thermal performance of the DBC substrate is reduced due to copper removal regions associated with forming the dimples raising the thermal resistance.

Disclosed aspects include a semiconductor device comprising a DBC substrate including a plurality of indentations in at least a top side of a ceramic substrate. The plurality of indentations are filled with a metal filler to provide metal filled dimples. A top copper layer is a patterned layer that is on the top side and provides at least leads, and there is at least one semiconductor die having bond pads electrically connected to the leads.

### BRIEF DESCRIPTION OF THE DRAWINGS

Reference will now be made to the accompanying drawings, which are not necessarily drawn to scale, wherein:

FIGS. 1A-D are successive cross-sectional views of an in-process DBC substrate corresponding to results following steps in an example method for forming a DBC substrate having indentations formed in the ceramic substrate that are metal filled, according to an example aspect. FIG. 1A shows the ceramic substrate being initially unpatterned. There are generally a plurality of ceramic substrates in the form of a two dimensional sheet (or a panel) that are simultaneously processed. FIG. 1B shows the ceramic substrate after forming indentations on both a top side and a bottom side. FIG. 1C shows the ceramic substrate after the indentations are filled with a metal filler to form metal filled dimples. FIG. 1D shows the DBC substrate after bonding a top copper layer to the top side of the ceramic substrate and a bottom copper layer to the bottom side of the ceramic substrate.

FIG. 2A shows a top view of a power module comprising a disclosed DBC substrate including four semiconductor die with the top copper layer being a patterned layer shown providing three die pads that are all electrically isolated from one another by spacing between the die pads that reveals the ceramic substrate, according to an example aspect. Metal filled dimples which are under the top copper layer (thus not visible in this top view) are still shown to enable this FIG. to show these features metal filled dimples are shown as circles positioned at the respective corners of the first top layer portion, under the die and extending beyond the die for the second top layer portion, and framing a perimeter of the third top layer portion.

FIG. 2B is a cross-sectional view of the portion of the power module shown in FIG. 2A that utilizes the second top layer portion that also includes leads showing a wirebond arrangement including bond wires between bond pads on the die and the leads, where the area of the die is entirely over the metal filled dimples. FIG. 2C is a cross-sectional view of a portion of the power module shown that utilizes a top copper layer showing a wirebond arrangement between bond pads on a die on a die pad, where the metal filled dimples are positioned on both sides of the power module beyond the area of the die.

FIG. 2D is a cross-sectional view of a portion of a power module shown that utilizes a top copper layer shown as a flip chip bonding arrangement between bond pads on a die shown utilizing solder balls to make a connection to leads provided by the top copper layer. The die is shown positioned entirely over the metal filled dimples.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this Disclosure.

Also, the terms “connected to” or “connected with” (and the like) as used herein without further qualification are intended to describe either an indirect or direct electrical connection. Thus, if a first device “connects” to a second device, that connection can be through a direct electrical connection where there are only parasitics in the pathway, or through an indirect electrical connection via intervening items including other devices and connections. For indirect connecting, the intervening item generally does not modify the information of a signal but may adjust its current level, voltage level, and/or power level.

To solve the DBC substrate problems described above, metal filled dimples where metal filler fills indentations formed in the ceramic substrate are utilized for disclosed aspects. The metal filler in the metal filled dimples act as anchors for the respective copper layers in the case of both a top copper layer and a bottom copper layer, which improves the mechanical reliability of the DBC substrate. The thermal performance of the disclosed DBC substrate is also improved because the thermal path through the ceramic substrate due to the metal filled dimples being filled with a metal such as copper becomes shorter in distance as compared to the thermal path when the DBC substrate includes a conventional ceramic substrate where the thermal path is through a full thickness of the ceramic substrate.

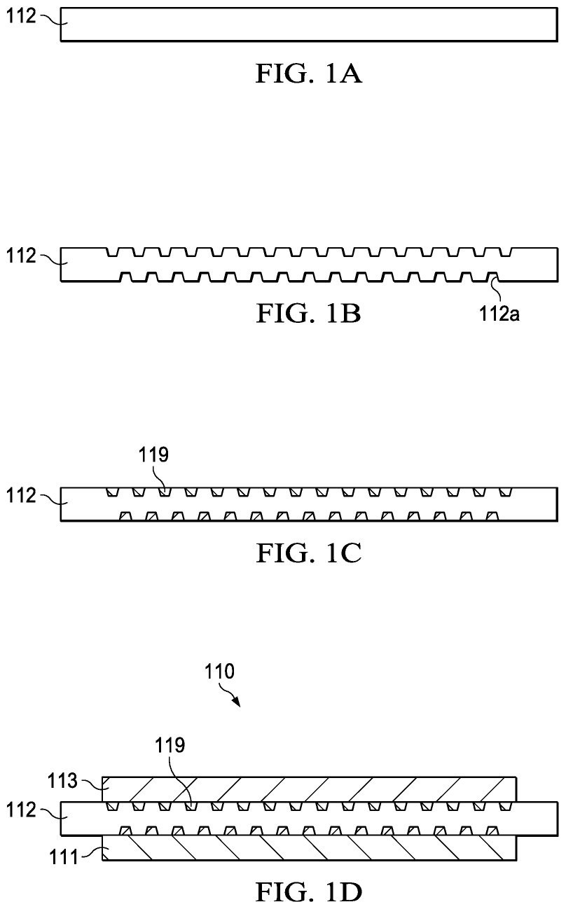

FIGS. 1A-D are successive cross-sectional views of an in-process DBC substrate corresponding to results following steps in an example method for forming a DBC substrate having indentations formed in the ceramic substrate that are metal filled, according to an example aspect. Although not shown, as described above multiple ones of the DBC substrate can be formed together in a sheet and after die mounting and wirebonding in the case of a wirebond package singulated at this stage to separate individual device units using, for example, using mechanical sawing.

FIG. 1A shows the ceramic substrate 112 being initially unpatterned. A typical thickness for the ceramic substrate 112 is 150 um˜650 um. The ceramic substrate 112 can comprise various ceramic materials, such as alumina (Al₂O₃), aluminum nitride (AlN), or silicon nitride.

FIG. 1B shows the ceramic substrate 112 after forming indentations 112a on both a top side and a bottom side. The indentations 112a when comparing locations on the top side and on the bottom side are shown by example being offset in position from one another so that they do not overlap. A variety of different material removal processes can be used to form the indentations 112a including laser ablation, sandblasting, and waterjetting. Indentation 112a depths can be varied, but the indentation depth will generally not exceed the 50% of ceramic substrate 112 thicknesses because there is a risk of breaking up the ceramic material due to its brittleness.

A typical range for the depth of the indentation 112a is 30% to 45% of the thickness of ceramic substrate 112. A depth of less than 30% can result in a significant loss in thermal performance. When the indentations 112a are offset in position, their depth can approach the thickness of the ceramic substrate 112, but when exceeding 50% of ceramic substrate thickness the risk of ceramic material breakage increases correspondingly. In the case of no indentation offset, there are limitations in the depth of the indentations 112a to avoid shorting through the ceramic substrate 112. A typical shape for the indentations 112a is generally a half-ellipsoid shape or half-sphere shape. However, based on the fabrication method, the shape can be other shapes such as cylindrical.

FIG. 1C shows the ceramic substrate 112 after the indentations 112a are filled with a metal filler to form metal filled dimples 119. The metal filler generally comprises copper to match the respective copper layers. A variety of different filling processes can be used to form the metal filled dimples 119, including for example electroless plating, electroplating and polishing, metal powder filling, and metal paste screen printing.

FIG. 1D shows an example DBC substrate as 110 after bonding a top copper layer 113 to the top side of the ceramic substrate 112 and a bottom copper layer 111 to the bottom side of the ceramic substrate 112. Because of the presence of the metal filled dimples 119, bonding of the top copper layer 113 and bottom copper layer 111 is to the ceramic of the ceramic substrate 112 and to the metal of the metal filled dimples 119 which become thermally and electrically connected together by the respective copper layers. Disclosed bonding thus forms a stronger bond as compared to conventional bonding which only provides copper to ceramic bonding. Possible bonding processes include the conventional DBC copper layer formation bonding methods of high-temperature eutectic bonding, or active metal brazing. These respective processes for implementing the method are each compatible with conventional DBC substrate formation equipment.

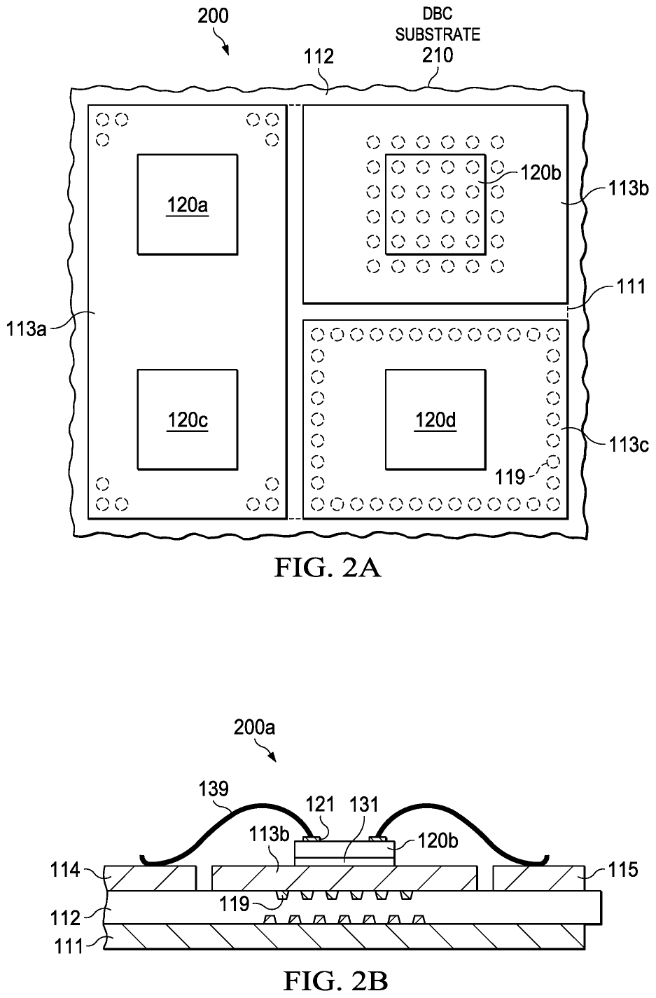

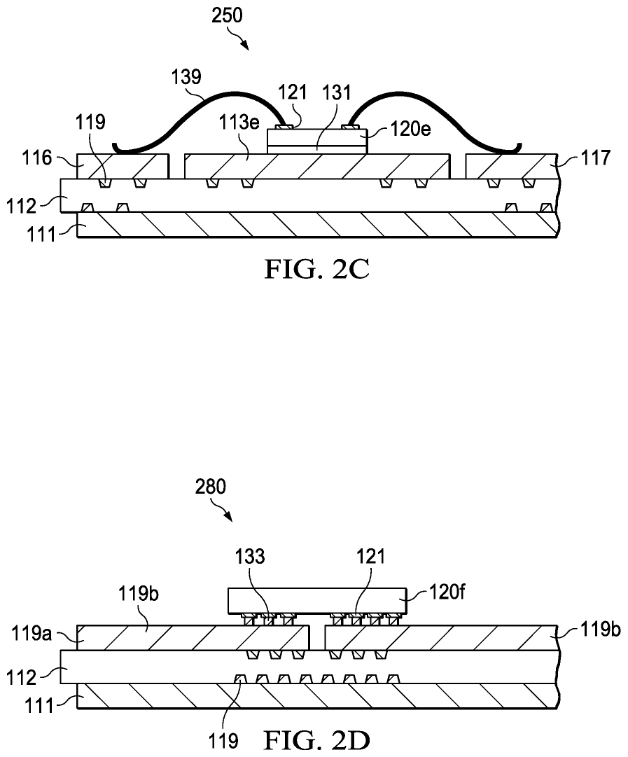

FIG. 2A shows a top view of a power module 200 comprising a disclosed DBC substrate 210 including four semiconductor die shown as 120a b, c and d shown with the top copper layer being a patterned layer providing three die pads shown as 113a, 113b, and 113c. The die pads are all electrically isolated from one another by a spacing between the die pads that reveals the ceramic substrate 112. Although not shown, the top copper layer also generally provides leads along its perimeter. Metal filled dimples which are under the top copper layer (thus not normally visible in this top view) are shown as 119 to include this information in this FIG. Although not shown, disclosed power modules may include molding.

On the first die pad 113a there is shown two die 120a, 120c spaced apart from one another. On the second die pad 113b and on the third die pad 113c there is shown a single die (120b, and 120d, respectively). Each die pad 113a, 113b, and 113c is shown by example having a different metal filled dimple 119 pattern thereunder. The first die pad 113a has metal filled dimples 119 only along its corners. The second die pad 113b has metal filled dimples 119 under the full area of the die 120b, with metal filled dimples 119 extending beyond the area of the die 120b. The third die pad 113c has metal filled dimples 119 along its full perimeter.

In general, the metal filled dimples can be positioned in the relatively high-stress areas of the power module which can be identified based on stress data that may be obtained for example from thermo-mechanical simulations or empirical testing. The high-stress areas lead to weak points of the power module that risk delamination, for example in the delamination of the top copper layer shown by its die pad portions 113a, b, c as well as the bottom copper layer 111 all from the ceramic substrate 112.

The die 120a, 120c can comprise discrete power die, or although not shown can also be on a single die, such as comprising a Si (or gallium nitride or SiC) field effect transistor (FET), or a Si insulated gate bipolar transistor (IGBT). The die 120b, d can each be different wide bandgap integrated circuit (IC) power devices (SiC/GaN)), and for example can comprise a gate driver and a controller.

FIG. 2B is a cross-sectional view of the portion of the power module 200 shown in FIG. 2A now shown as 200a that utilizes the die pad 113b that on the same copper layer also includes leads 114 and 115 showing a wirebond arrangement including bond wires 139 between bond pads 121 on the die 120b and the leads 114 and 115, where the area of the die 120b is entirely over the metal filled dimples 119.

FIG. 2C is a cross-sectional view of a portion of the power module shown as 250 that utilizes a top copper layer that provides a die pad shown as 113e and leads 116 and 117 showing a wirebond arrangement with bond wires 139 between bond pads 121 on a die shown as 120e on the die pad 113e. The metal filled dimples 119 are positioned on both sides of the power module 250 beyond the area of the die 120e.

In case of power module 200a as shown in FIG. 2B, the metal filled dimples 119 being under the die 120b function to release the thermo-mechanical stress in the die attach layer 131. For example, the die attach layer material may comprise solder, or epoxy so the metal filled dimples 119 improve the reliability performance, especially the temperature cycle test, and power cycle test. At the same time, the metal filled dimples 119 each provide an additional thermal path. The ceramic layer's 112 (in the case of conventional alumina) thermal conductivity (10˜18 W/m·K) is much lower than that of Cu (˜360 W/m·K) used for the top and bottom copper layers, so that the metal filled dimples lower the thermal resistance.

In case of the power module 250 shown in FIG. 2C generally DBC substrate delamination occurs at the edge of the copper layer patterns because of the CTE mismatch between the ceramic substrate 112 and the respective copper layers. The metal filled dimples also improves the delamination resistance of the DBC substrate, resulting in a reliability improvement.

FIG. 2D is a cross-sectional view of a portion of a power module shown as 280 that utilizes a top copper layer shown as leads 119a, 119b showing a flipchip bonding arrangement between bond pads 121 on a die shown as 120f utilizing solder balls 133 to make a connection to leads 119a, b provided by the top copper layer. The die 120f is shown positioned entirely over the metal filled dimples 119.

### EXAMPLES

Disclosed aspects are further illustrated by the following specific examples, which should not be construed as limiting the scope or content of this Disclosure in any way.

A simulation was performed that compared the thermal performance of a power module including a disclosed DBC substrate resembling that shown in FIG. 2C having copper filled dimples formed in the ceramic substrate and a conventional DBC substrate not having any dimples, with the ceramic substrates both comprising alumina. Bond pads of a semiconductor die were connected by bond wires to leads provided by the top copper layer, and the power modules were operated at a power level of 5 kW, with a power loss of 20 W. The ambient temperature was 25° C. The maximum temperature reached for the power module including a disclosed DBC substrate was 55.23° C. thus having a 1.51 K/W Rₜₕ (thermal resistance), and the maximum temperature for the same power device but having a conventional DBC substrate reached was 60.65° C. thus having a 1.78 K/W Rₜₕ that is 18% higher as compared to the power device having the disclosed DBC substrate.

Disclosed aspects can be integrated into a variety of assembly flows to form a variety of different semiconductor packages and related products. The semiconductor package can comprise a single power device die or multiple power device die, such as configurations comprising a plurality of stacked power device die, or laterally positioned power device die. A variety of package substrates may be used. The power device die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the power device die can be formed from a variety of processes including bipolar, insulated-gate bipolar transistor (IGBT), CMOS, BiCMOS and MEMS.

Those skilled in the art to which this Disclosure relates will appreciate that many variations of disclosed aspects are possible within the scope of the claimed invention, and further additions, deletions, substitutions and modifications may be made to the above-described aspects without departing from the scope of this Disclosure.

1. A semiconductor device, comprising:
a direct bonded copper (DBC) substrate including:
a plurality of indentations in at least a top side of a ceramic substrate;
the plurality of indentations filled with a metal filler to provide metal filled dimples;
a top copper layer being a patterned layer on the top side providing leads, and
at least one semiconductor die having bond pads electrically connected to the leads.

2. The semiconductor device of claim 1, wherein the DBC substrate further includes a bottom copper layer, and wherein the metal filled dimples include a first portion under the top copper layer and a second portion under the bottom copper layer.

3. The semiconductor device of claim 2, wherein positions of the first portion are offset relative to positions of the second portion.

4. The semiconductor device of claim 1, wherein the metal filler comprises copper, and wherein a depth of the plurality of indentations is 30% to 45% of a thickness of the ceramic substrate.

5. The semiconductor device of claim 1, wherein the plurality of indentations collectively extend over an entire area of the semiconductor die.

6. The semiconductor device of claim 1, wherein the bond pads are electrically connected to the leads by a flipchip bonding arrangement.

7. The semiconductor device of claim 1, wherein the top copper layer further comprises a die pad, wherein the semiconductor die is attached with a top side up on the die pad, and wherein the bond pads are electrically connected to the leads by bond wires.

8. The semiconductor device of claim 1, wherein the semiconductor die comprises a first semiconductor die and at least a second semiconductor die, and wherein the top copper layer is a patterned layer that provides a plurality of die pads.

9. The semiconductor device of claim 8, wherein the first semiconductor die comprises a discrete power transistor, and wherein the second semiconductor die comprises a power integrated circuit (IC).

10. A method, comprising:
forming a direct bonded copper (DBC) substrate, including:
forming a plurality of indentations in at least a top side of a ceramic substrate;
filling the plurality of indentations with a metal filler to form metal filled dimples;
bonding a top copper layer on the top side, and
patterning the top copper layer to provide at least leads.

11. The method of claim 10, wherein the bonding further includes a bonding of a bottom copper layer on the bottom side, and wherein the plurality of metal filled dimples include a first portion under the top copper layer and a second portion under the bottom copper layer.

12. The method of claim 11, wherein positions of the first portion are offset relative to positions of the second portion.

13. The method of claim 10, wherein the metal filler comprises copper and wherein a depth of the plurality of indentations is 30% to 45% of a thickness of the ceramic substrate.

14. The method of claim 10, further comprising electrically connecting bond pads of at least one semiconductor die to the leads to provide a semiconductor device.

15. The method of claim 13, wherein the plurality of indentations collectively extend over an entire area of the semiconductor die.

16. The method of claim 14, further comprising determining positions for the metal filled dimples from identified high stress areas of the semiconductor device based on thermo-mechanical simulations or empirical test results.

17. The method of claim 10, wherein a depth of the plurality of indentations is 30% to 45% of a thickness of the ceramic substrate.

18. The method of claim 10, wherein the top copper layer further comprises a die pad wherein the semiconductor die is attached with a top side of on the die pad, and wherein the bond pads are electrically connected to the leads by bond wires.

19. The method of claim 10, wherein the semiconductor die comprises a first semiconductor die and at least a second semiconductor die, and wherein the top copper layer is a patterned layer that provides a plurality of die pads.

20. The method of claim 19, wherein the first semiconductor die comprises a discrete power transistor, and wherein the second semiconductor die comprises a power integrated circuit (IC).
